(19) United States
(12) Patent Application Publication
(10) Pub. No.: US 2013/0092739 A1
(43) Pub. Date: Apr. 18, 2013

(54) SIMPLE MULTIFUNCATIONAL IDENTIFICATION LABELS AND THEIR MANUFACTURING METHOD

(71) Applicant: SHENG-CHANG HUANG, KAOHSIUNG CITY (TW)

(72) Inventor: SHENG-CHANG HUANG, KAOHSIUNG CITY (TW)

(73) Assignees: SUPREME TECHNIC PACKAGE CO., LTD., KAOHSIUNG CITY (TW); SHENG-CHANG HUANG, KAOHSIUNG CITY (TW)

(21) Appl. No.: 13/273,124

(22) Filed: Oct. 13, 2011

(51) Int. Cl. G06K 19/077; H05K 13/00; B32B 37/12; B05D 5/12; C23F 1/02

(52) U.S. Cl. 235/488; 235/492; 427/96.1; 216/13; 156/250; 29/592.1

(57) ABSTRACT

Simple multifunctional identification labels and their manufacturing method includes a basic plate formed with an outer surface and an inner surface, and plural radio frequency identification systems are respectively provided with circuits and radio frequency identification chips. The radio frequency identification systems are installed on the outer surface of the basic plate to make up plural identification labels, which are then cut and shaped into many individual simple multifunctional identification labels, quick in manufacturing. The simple multifunctional identification labels of this invention can be directly used as articles and needless to be additionally combined with other articles, able to elevate the practicability of the identification labels.

### BACKGROUND OF THE INVENTION

1. Field of the Invention

This invention relates to simple multifunctional identification labels and their manufacturing method, able to have a plurality of identification labels formed integrally at the same time. Then, the identification labels are cut into many individual simple and multifunctional identification labels that can respectively be used as an article and needless to be additionally combined with other articles for use, quick in manufacturing, low in manufacturing cost and able to elevate practicability of the identification labels.

2. Description of the Prior Art

For the present, use of identification chips has become more and more popular, and identification labels are considerably employed for expensive articles, low-priced articles, daily necessities, breeding and animal husbandry or article management so as to facilitate management or record of articles. In order to make identification labels become comparatively popular in use, the most important factor to be considered is the cost of manufacturing an article with an identification label.

Generally, the application of a conventional identification label is to have an identification chip made into a product with an identification label through multiple processing, such as an in-mold labeled product manufactured by in-mold labeling technique, or a product having identification function, which is made in a way of embedding. In other words, the conventional identification label is fixed in the interior of an article to let the article possess identification function in a way of integral shaping or in various ways of combination.

One conventional identification label, as disclosed in a Taiwan patent No. M394533, titled “IMPROVEMENT FOR THE STRUCTURE OF A RFID PIG'S EAR TAG”, is to have an IC card placed on a tag disc and, through secondary in-mold plastic injection molding, formed into an upper cover layer to completely sheathe the IC card in the interior of an ear tag body, letting the ear tag possess a function of identification. This conventional RFID pig's ear tag is the structure of an ear tag with RFID embedded in an article, but such an ear tag must be manufactured through multiple processing, and it can only produce one ear tag with RFID once, thus not conforming to economical gain.

Another conventional identification tag, as disclosed in a Taiwan patent No. M347639, titled “HOLDER DEVICE WITH RFID TAG”, is to have a RFID tag embedded in a main body of the holder device when a clamping body is manufactured, letting the clamping body possess a function of identification. The holder device with RFID tag has to be processed several times to make up an article with a radio frequency identification tag, and it can only produce one clamping body with RFID tag with one round, not tallying with economical gain.

Specifically, the conventional identification tag mentioned above can be employed only after the identification tag is combined with an article and made into an in-mold tagged product through in-mold tagging technique, or made into an article possessing an identification function in a way of embedding. That is, the conventional identification tag cannot individually serve as an article for use, thus greatly restricted in application value and range of the identification tags. In addition, only after being processed for several times can an article with the identification tag be used, thus increasing cost and not conforming to economical gain.

### SUMMARY OF THE INVENTION

The objective of this invention is to offer simple multifunctional identification labels and their manufacturing method, able to be manufactured with quickness and in large quantity and able to be used as an article, lowering manufacturing cost and elevating practicability of the identification labels.

The method of manufacturing simple multifunctional identification labels includes a basic plate formed with an outer surface and an inner surface. The outer surface of the basic plate is provided with a plurality of radio frequency identification systems to form a plurality of identification labels, which are then cut into many individual simple multifunctional identification labels, quick in manufacturing. Each simple multifunctional identification label can be directly used as an article and needless to be additionally combined with other articles, thus elevating practicability of the simple multifunctional identification labels.

In addition, the outer surface of the basic plate can be provided thereon with a protective layer for protecting the radio frequency identification systems. The basic plate together with the radio frequency identification systems and the protective layer are combined together to make up a plurality of identification labels, which are then cut into many individual simple multifunctional identification labels. Each individual simple multifunctional identification label can further be cut and shaped into a clasp-type identification label or a perforation type identification label, or cut into various geometric-shaped identification labels, such as a rectangular shape, a circular shape, a polygonal shape or an irregular shape, able to increase functions of the identification labels.

### BRIEF DESCRIPTION OF DRAWINGS

This invention will be better understood by referring to the accompanying drawings, wherein:

FIG. 1 is a cross-sectional view of a first preferred embodiment of simple multifunctional identification labels and their manufacturing method in the present invention.

FIG. 2 is a flow chart of a manufacturing method of the first preferred embodiment of simple multifunctional identification labels and their manufacturing method in the present invention;

FIG. 3 is a cross-sectional view of a second preferred embodiment of simple multifunctional identification labels in the present invention;

FIG. 4 is a flow chart of a manufacturing method of the second preferred embodiment of simple multifunctional identification labels in the present invention;

FIG. 5 is a perspective view of a large-sized basic plate formed thereon with plural identification labels respectively provided with a RFID system in the present invention;

FIG. 6 is a perspective view of a long basic plate formed thereon with plural identification labels respectively provided with a RFID system in the present invention;

FIG. 7 is a plain view of a clasp-type identification label in the present invention;

FIG. 8 is a perspective view of the clasp-type identification label in a clasp condition in the present invention;

FIG. 9 is a perspective view of a perforation type identification label in the present invention;

FIG. 10 is a perspective view of a circular-shaped identification label in the present invention;

FIG. 11 is a perspective view of a rectangular-shaped identification label in the present invention; and

FIG. 12 is a perspective view of an irregular-shaped identification label in the present invention.

### DETAILED DESCRIPTION OF THE PREFERRED EMBODIMENT

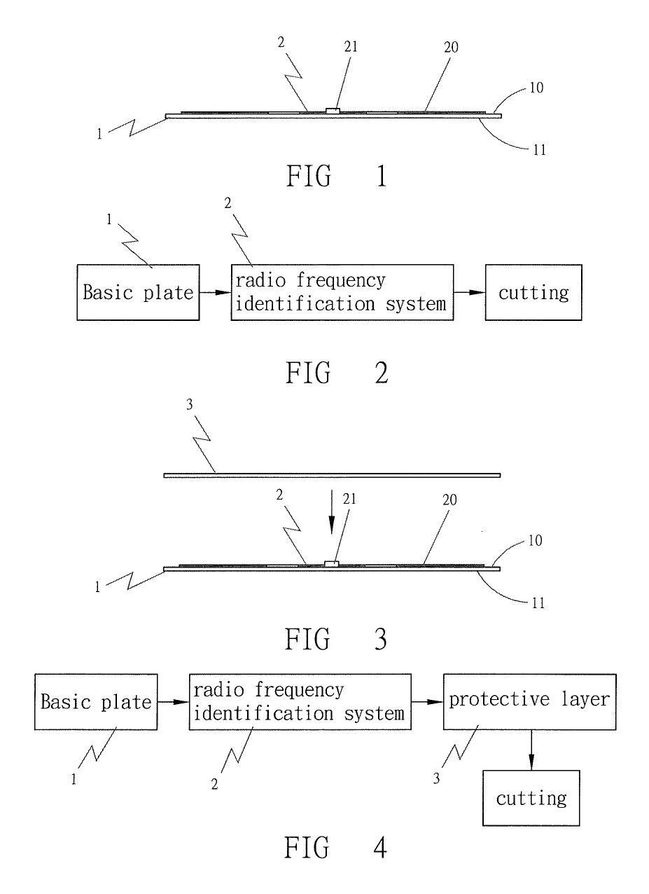

A first preferred embodiment of simple multifunction labels and their manufacturing method in the present invention, as shown in FIGS. 1 and 2, includes a basic plate 1, plural radio frequency identification systems 2 (RFID) as main components combined together.

The basic plate 1 formed with an outer surface 10 and an inner surface 11 can be made into a large-sized basic plate, as shown in FIG. 5, or into a long basic plate, as shown in FIG. 6, in accordance with requirements of manufacturing, and can be made into a thick basic plate or a thin basic plate according to needs of use. The basic plate 1 can be made of paper, plastic, copper foil or other materials so long as the outer surface 10 of the basic plate 1 is able to receive a plurality of radio frequency identification systems 1. Further, the basic plate 1 can be printed with patterns or characters in advance for beautifying the identification labels.

The radio frequency identification system (RFID) 2 is provided with circuits 20 and radio frequency identification chips 21. If the basic plate 1 is made of paper, plastic or other materials, the outer surface 10 of the basic plate 1 can be printed with circuits 20 by printing technique, and if the basic plate 1 is made of copper foil or other metal foils, the outer surface 10 of the basic plate 1 can be etched with circuits 20 through etching technique. Then, the radio frequency identification chips 21 are stuck to the outer surface 10 of the basic plate 1 that is provided with the circuits 20 via surface adhesion technique, letting plural radio frequency identification systems 2 able to be disposed on the outer surface 10 of the basic plate 1 to form a plurality of identification labels, as shown in FIGS. 5 and 6. Afterward, the plural identification labels are cut into many individual simple multifunctional identification labels.

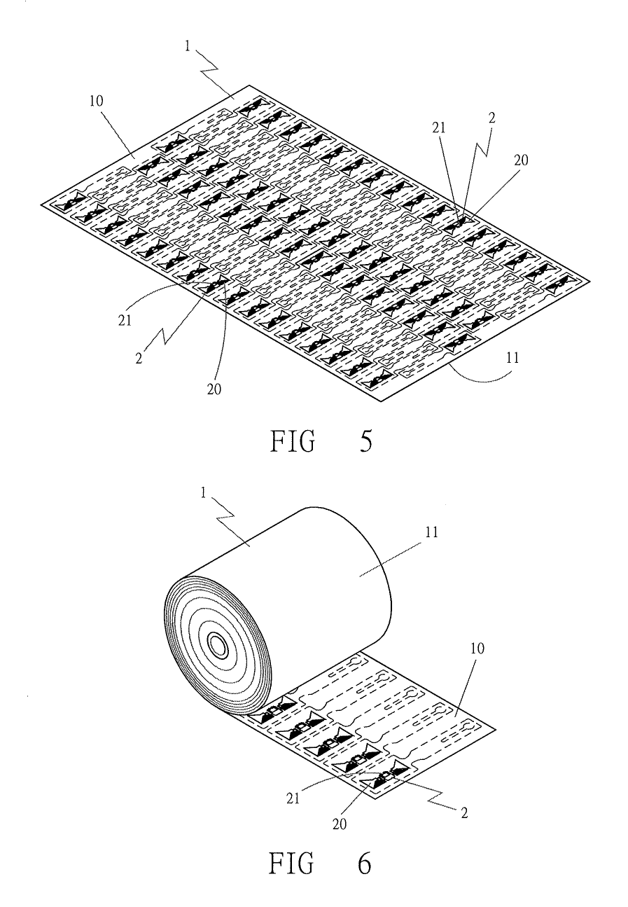

A second preferred embodiment of simple multifunctional identification labels and their manufacturing method in the present invention, as shown in FIGS. 3 and 4, is to have a protective layer 3 fixed on both the outer surface 10 of the basic plate 1 and the radio frequency identification systems 2 for protecting the identification labels. The protective layer 3 can be a sticking material coated on the outer surface 10 of the basic plate 1 and the radio frequency identification systems 2, or a protective film stuck to the outer surface 10 of the basic plate 1 and the radio frequency identification system 2. The basic plate 1 or the protective layer 3, or both the basic plate 1 and the protective layer 3 can be printed thereon with patterns or characters in advance or after finishing manufacturing of the identification labels for beautifying the identification labels and producing a stereoscopic visual effect. The protective layer 3 matches with the basic plate 1 in shape, and after the basic plate 1 together with the radio frequency identification systems 2 and the protective layers are combined to make up plural identification labels, as shown in FIGS. 5 and 6, the identification labels are cut and shaped into many single simple multifunctional identification labels.

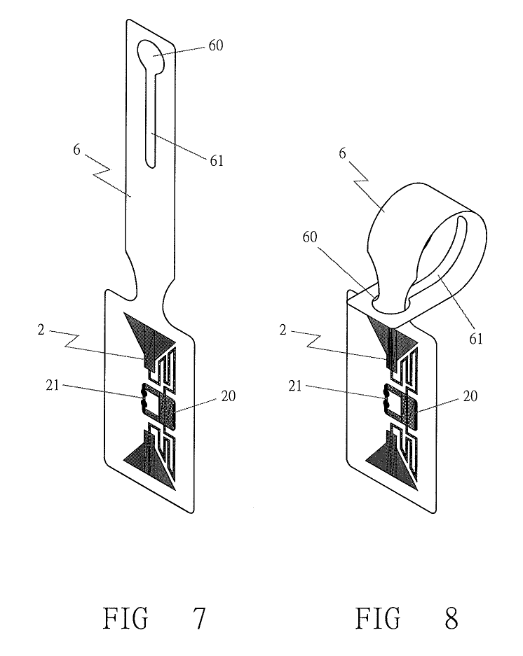

Referring to FIGS. 7 and 8, foresaid each shaped simple multifunctional identification label can be cut to form a retaining ring type identification label 6 having one end provided with the radio frequency identification system 2 and another end cut with a slot 61 with a circular hole 60 at one end. The retaining ring type identification label 6 is formed by having one end, which is provided with the RFID system 2, inserted through the elongate slot 61 and then transposed for an angle to be stuck in the circular hole 60. Thus, the retaining ring type identification label 6 can be directly fitted on an article, on an animal body or around a wrist, convenient to deal with or manage various businesses.

Referring to FIG. 9, foresaid each shaped simple multifunctional identification label can be cut into a perforation type identification label 7, which is bored with an insert hole 70 at a proper location, so that the perforation type identification label 7 can be directly hung or inserted on an article.

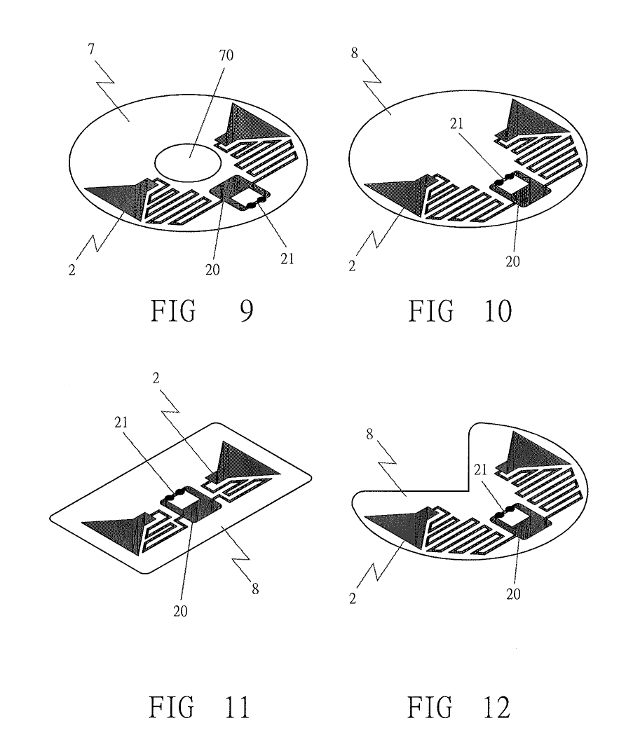

Referring to FIGS. 10 and 12, foresaid each shaped simple multifunctional identification label can be cut into various geometric-shaped identification label 8, such as a rectangular shape, a circular shape, a polygonal shape or an irregular shape. Thus, the geometric-shaped identification label 8 can be deposited in a packaging bag or in an article or made into a sticky identification label to be directly stuck on an article, increasing the function of the identification labels.

To sum up, the simple multifunctional labels and their manufacturing method of this invention can integrally make up a plurality of identification labels respectively possessing a radio frequency identification system 2 at the same time, letting the identification labels either formed into a large-sized sheet shape or wound into a cylindrical shape. Then, the identification labels are cut into many individual simple multifunctional identification labels with various shapes, quick in manufacturing and low in manufacturing cost. Moreover, the simple multifunctional identification labels of this invention can directly be employed for identifying articles and needless to be additionally combined with other articles, enabling the identification labels to be used more extensively, enhancing practicability of the identification labels and conforming to economical gain.

While the preferred embodiments of the invention have been described above, it will be recognized and understood that various modifications may be made therein and the appended claims are intended to cover all such modifications that may fall within the spirit and scope of the invention.

What is claimed is:

1. Simple multifunctional identification labels and their manufacturing method comprising:
a basic plate formed with an outer surface and an inner surface; and
plural radio frequency identification systems provided with circuits and radio frequency identification chips, said plural radio frequency identification systems installed on said outer surface of said basic plate to make up plural identification labels, then said plural identification labels cut into many individual simple multifunctional identification labels, quick in manufacturing said simple multifunctional identification labels, each said simple multifunctional identification label able to be directly used as an article and needless to be additionally combined with other articles, thus elevating practicability of said simple multifunctional identification labels.

2. Simple multifunctional identification labels and their manufacturing method as claimed in claim 1, wherein said basic plate is made of paper, plastic or other materials, and said outer surface of said basic plate is printed with circuits via printing technique.

3. Simple multifunctional identification labels and their manufacturing method as claimed in claim 1, wherein said basic plate is made of copper foil or other metal foils, and said outer surface of said basic plate is etched with circuits through etching technique.

4. Simple multifunctional identification labels and their manufacturing method as claimed in claim 1, wherein said radio frequency identification chips are firmly fixed on said basic plate with said circuits by surface adhesion technique.

5. Simple multifunctional identification labels and their manufacturing method as claimed in claim 1, wherein said basic plate is printed with patterns or characters in advance or after finishing manufacturing of said identification labels.

6. Simple multifunctional identification labels and their manufacturing method as claimed in claim 1, wherein a protective layer is provided on said outer surface of said basic plate, said basic plate together with said radio frequency identification systems and said layer combined to form plural identification labels.

7. Simple multifunctional identification label and their manufacturing method as claimed in claim 6, wherein said protective layer is provided on both said outer surface of said basic plate and said radio frequency identification systems by means of gluing sticking a protective film,

8. Simple multifunctional identification labels and their manufacturing method as claimed in claim 6, wherein said basic plate or said protective layer, or both said basic plate and said protective layer can be printed with patterns or characters beforehand or after finishing manufacturing of said identification labels to let said identification labels look beautiful and produce stereoscopic visual effect.

9. Simple multifunctional identification labels and their manufacturing method as claimed in claim 1, wherein said inner surface of said basic plate is coated with a gluing material.

10. Simple multifunctional identification labels and their manufacturing method comprising:
a basic plate formed with an outer surface and an inner surface, said outer surface of said basic plate installed with radio frequency identification systems to form retaining ring type identification labels, each said retaining ring type identification label having one end equipped with said radio frequency identification system and another end cut with an elongate slot, said elongate slot having an end bored with a circular hole, one end of said retaining ring type identification label, which provided with said radio frequency identification system, directly inserted through said slot at another end and then transposed for an angle to be stuck to said circular hole, thus said retaining ring type identification label able to be fitted on an article or an animal body or around a wrist.

11. Simple multifunctional identification labels and their manufacturing method comprising:
a basic plate formed with an outer surface and an inner surface, said outer surface of said basic plate disposed with radio frequency identification systems for producing perforation type identification labels, each said perforation type identification label bored with an insert hole by which said perforation type identification label can be hung or fixed on an article.

12. Simple multifunctional identification labels and their manufacturing method comprising:
a basic plate formed with an outer surface and an inner surface, said outer surface of said basic plate provided with radio frequency identification systems for producing identification labels, said identification labels able to be placed in a packaging bag or in an article, or made into sticky identification labels to be stuck on an article, increasing functions of identification labels.

13. Simple multifunctional identification labels and their manufacturing method as claimed in claim 11, wherein said identification labels is of any geometric shape, such as a rectangular shape, a circular shape, a polygonal shape, an irregular shape or a shape of an article.
